(19) United States
(12) Patent Application Publication
(10) Pub. No.: US 2004/0205446 A1
(43) Pub. Date: Oct. 14, 2004

(54) Decoding apparatus, decoding method, recording/reproducing apparatus, program storage medium, and program

(76) Inventor: Hiroyuki Yamagishi, Tokyo (JP)

Correspondence Address: JAY H. MAIOLI, Cooper & Dunham LLP, 1185 Avenue of the Americas, New York, NY, 10036, US

(21) Appl. No.: 10/780,191

(22) Filed: Feb. 17, 2004

(30) Foreign Application Priority Data
Feb. 21, 2003 (JP) P2003-043653

(51) Int. Cl. H03M 13/03

(52) U.S. Cl. 714/792

(57) ABSTRACT

The states S0 to S9 in a state-transition table, which is a combination of (d,k) Run Length Limited (RLL) codes and a Parallel Response (PR1) channel having a precoder, correspond to ten states defined by dividing each of the five states S0 to S4 in the state-transition table used to encode data into (d,k) RLL codes. That is, the states S0 to S4 correspond to the cases where the immediately preceding Non Return to Zero (NRZ) code is “0” in the state-transition table of the (d,k) RLL codes, and the states S5 to S9 correspond to the cases where the immediately preceding NRZ code is “1” in the state-transition table of the (d,k) RLL codes. This method can be applied to recording/reproducing apparatuses.

### BACKGROUND OF THE INVENTION

1. Field of the Invention

The present invention relates to a decoding apparatus, a decoding method, a recording/reproducing apparatus, a program-stored medium, and a program. More particularly, the invention relates to a decoding apparatus and a decoding method which are fit for use in decoding encoded data by using a finite state transition diagram, and also to a recording/reproducing apparatus, a program-stored medium and a program.

This application claims the priority of the Japanese Patent Application No. 2003-4043653 filed on Feb. 21, 2003, the entirety of which is incorporated by reference herein.

2. Description of the Related Art

A series of codes is detected in a recording/reproducing system that performs magnetic recording or optical recording. To be detected in such a system, the code series is equalized to have PR (Parallel Response) characteristic so that the codes may be well recorded and reproduced for a specific channel. Once so processed, the codes have noise suppressed and can therefore acquire a good error-rate characteristic.

In a recording/reproducing system that uses error-correcting codes such as RS (Reed-Solomon) codes, a channel detector is used. The channel detector is, for example, a viterbi decoder that uses a trellis diagram for the PR channel to perform the maximum likelihood decoding method or a BCJR (Bahl-Cocke-Jeinek-Raviv) decoder that performs maximum a posteriori probability (MAP) decoding. The BCJR algorithm is a MAP algorithm that infers information, bit by bit, from a series of codes received, which has length N, if the initial state that the encoder has at first and the final state that the encoder has at time N are known.

Turbo codes or LDPC (Low Density Parity Check) codes can be decoded by repeatedly using an SISO (Soft-Input, Soft-Output) APP (a posteriori probability) detector that usually uses FBA (Forward-Backward Algorithm) or message-passing algorithm.

In a system wherein turbo codes and PR channels are combined, the channel detector is an APP detector that uses the MAP algorithm. Thus, an APP detector, which is connected to the output of the system and which detects the turbo codes, can utilize not only information consisting of “0s” and “1s,” but also the information (soft-decision information) representing which data has probability and how high the probability. The channel detector and the detector for detecting turbo codes are connected in cascade. (See, for example, T. Souvignier et al. “Turbo codes for PR4: Parallel versus serial concatenation,” Proc. ICC '99, pp. 1638-1642, 1999.)

In systems actually employed to magnetically or optically record and reproduce data, the codes are limited ones, such as RLL (Run Length Limited) codes or MTR (Maximum Transition Run) codes.

An RLL code is a code in which the number of “0s” between two “1s” is limited. It is represented as: (d, k) RLL, where d is the minimum run length and k is the maximum run length, either defined by “0s” between two “1s.” In NRZI (non return to zero inverted) recording, the RLL code can increase the minimum recording wavelength by limiting the minimum run length d and can facilitate the clock-signal reproduction achieved by a PLL (Phase Locked Loop) by limiting the maximum run length k.

MTR codes are used as trellis codes in a specific high-order PR equalization system. In this system, the trellis codes can increase the minimum Euclidean distance.

The conversion of these limited codes can be described in the form of a finite state transition diagram. The limited codes can be decoded by means of a sliding block decoder.

The sliding block decoder designed to decode limited codes, such as RLL codes and MTR codes decodes codes by using hard-decision information. Hence, it cannot be connected to APP detectors that utilize soft-decision information, it is difficult to combine any limited code with a turbo code that needs to be decoded by an APP detector.

It is proposed that MFM (Modified Frequency Modulation) codes, which are (1, 3) RLL codes, be decoded by means of SISO decoding. An MFM code is so modulated that its polarity changes at the mid-part of the data if the data is “1,” does not change at all if the data consists of one “0” only, and changes at the boundary if the data consists of continuous “0s.” Thus, the polarity can change at three different intervals, i.e., T, 1.5T and 2T. MFM codes can be recorded at density, twice as high as FM (Frequency Modulation) codes. They can undergo self-clock extraction. This is why encoding systems that generate MFM codes are widely employed.

Various methods of SISO-decoding codes recorded have been proposed, which may be employed to decode MFM codes. One method is to use an FBA and construct a trellis from the state transition diagram of an encoder (FBA decoder for trellis). A second method is to extract only one bit for every two bits of the channel data, thereby decoding information bits (i.e., systematic modulation codes), because MFM codes are systematic codes. A third method is to find the probability of information bits by comparing received signals with five types of all code series that can be generated for a window (i.e., slidingblock window) having a 3-bit constrained encoding length, because MFM codes are sliding block codes. (Refer to, for example, J. L. Fan, “CONSTRAINED CODING AND SOFT ITERATIVE DECODING,” Kluwer Academic Publishers, July 2001.)

A system is disclosed, in which the PR channel is combined with RLL codes. The (1,7) RLL codes are decoded by a method that uses a slidingblock window. (See, for example, L. L. McPheters et al., “Turbo-Coded Optical Recording Channels with DVD Minimum Mark Size,” IEEE Trans. Magn., Vol. 38, No. 1, pp. 298-302, 2002.)

FIG. 1 is a block diagram showing a conventional recording/reproducing apparatus 1.

The recording/reproducing apparatus 1 comprises an encoding section 11, a recording/reproducing section 12, and a decoding section 13. The encoding section 11 encodes data input to the apparatus 1. The recording/reproducing section 12 receives encoded data from the encoding section 11, records the data in a recording medium, reads the data from the recording medium, and supplies the data to the decoding section 13. The decoding section 13 detects codes from the coded data supplied from the recording/reproducing section 12 and decodes the codes detected.

The encoding section 11 comprises an LDPC encoding unit 21, an RLL encoding unit 22, and an NRZI/NRZ converting unit 23. In the encoding section 11, the LDPC encoding unit 21 encodes the input data into an LDPC code and the RLL encoding unit 22 encodes the LDPC code into, for example, a (2, 7) RLL-coded data.

FIG. 2 is a five-state transition diagram that describes how the input data is encoded into (2, 7) RLL codes, at an encoding ratio of 1:2. In FIG. 2, the circles indicate various states. The symbol added to each arrow shown in FIG. 2 represents the input information bit and the output code bits. This state-transition diagram is identical to the diagram disclosed in T. D. Howell, “Statistical property of selected recording codes,” IBM J. Res. Develop., Vol. 33, No. 1, 1989, except that it defines the assingments of input bits.

As the five-state transition diagram of FIG. 2 depicts, the RLL encoding unit 22 outputs a code (01) if “0” is input to the encoding section 11 while the unit 22 remains in state S1. As a result, the state of the unit 22 changes, from state S1 to state S0. If “1” is input to the encoding section 11 while the unit 22 remains in state S1, the RLL encoding unit 22 outputs a code (01) and the state of the unit 22 changes, from state S1 to state S4.

The code output from the RLL encoding unit 22 is supplied to the NRZI/NRZ converting unit 23. The unit 23 converts the code to an NRZ (non return to zero) code. The NRZ code is supplied to the recording/reproducing section 12.

The recording/reproducing section 12 incorporates a recording medium. The section 12 receives the encoded data from the encoding section 11 and records this data in the recording medium. The section 12 reads the encoded data from the recording medium and outputs the encoded data to the decoding section 13.

The decoding section 13 comprises a PR equalization unit 31, a BCJR detecting unit 32, an RLL decoding unit 33, an LDPC decoding unit 34. In the decoding section 13, the encoded data is supplied to the PR equalization unit 31. The unit 31 performs prescribed PR equalization on the data, which acquires desired characteristics. The PR-equalized data is supplied to the BCJR detecting unit 32.

In the apparatus 1 , the recording/reproducing section 12 and the decoding section 13 constitute a recording/reproducing channel model. In the channel model, “0” and “1” contained in the NZR code supplied to the recording/reproducing section 12 are mapped into “+1” and “−1,” respectively, and the transfer function of PR1 (Partial Response Class−1) is: H(D)=(1+D)/2, where D is a delay operator.

It is known that the equalization of (1+D) to the xth power suppresses the high-frequency noise in signals reproduced, and therefore results in a high signal-to-noise ratio in recording/reproducing apparatuses. The equalization of (1+D) to the first power (x=1) is generally known as “PR1 equalization.” PR1 equalization is practically performed in, for example, magnetic recording/reproducing apparatuses of 3.8-m or 8-mm tape streamer type.

FIG. 3 is a state-transition diagram for a PR1 channel with a precoder, which has the restriction of d=2. As this state-transition diagram illustrates, “0” and “1” contained in the NZR code supplied to the recording/reproducing section 12 are mapped into “+1” and “−1,” respectively, and the transfer function of PR1 is: H(D)=(1+D)/2, where D is a delay operator. Of the label of each arrow, the numerals at the front and back of the virgule are the coded bit and the channel output, respectively.

As seen from the transition diagram of FIG. 3, the channel output from the PR equalization unit 31 is (+1) for a coded bit “0” if the recording/reproducing apparatus 1 assumes state S0. Thus, the apparatus 1 remains in state S0. The PR equalization unit 31 outputs (0) for a coded bit “1” if the recording/reproducing apparatus 1 assumes state S0. In this case, the state of the apparatus 1 changes to state S4.

Using a BCJR algorithm, the BCJR detecting unit 32 detects a code, which is supplied to the RLL decoding unit 33. In other words, the BCJR detecting unit 32 detects the code by using the trellis shown in FIG. 4 and designed for the PR1 channel having the precoder. It should be noted that the trellis of FIG. 4 corresponds to the state-transition diagram of FIG. 3.

As indicated above, the trellis shown in FIG. 4 corresponds to the state-transition diagram of FIG. 3. In the trellis of FIG. 4, each solid-line arrow represents a state transition that takes place if the input code bit is “0,” and each broken-line arrow depicts a state transition that occurs if the input code is “1.” Of the label of each arrow, the numerals at the front and back of the virgule are the coded bit and the channel output, respectively.

The RLL decoding unit 33 uses the trellis shown in FIG. 5 and corresponding to the state-transition diagram of FIG. 2, carrying out SISO RLL decoding (FBA decoder for trellis). The RLL-decoded data is supplied to the LDPC decoding unit 34. Thus, the trellis shown in FIG. 5 corresponds to the state-transition diagram of FIG. 2.

In the trellis of FIG. 5, each solid-line arrow represents a state transition that takes place if the input information bit is “0,” and each broken-line arrow depicts a state transition that occurs if the input code is “1.” Of the label of each arrow, the numerals at the front and back of the virgule are the information bit and the coded bit, respectively.

The LDPC decoding unit 34 performs LDPC decoding on the input signal, generating information bits. The information bits are output from the decoding section 13.

As already mentioned, the BCJR detecting unit 32 detects a series of recorded codes from the PR channel and the RLL decoding unit 33 decodes this code series, in the recording/reproducing apparatus 1 shown in FIG. 1. Nonetheless, the series of recorded codes can be decoded by means of a sliding-block window.

Hitherto it has been proposed that data should be encoded into RLL codes or MTR codes, which are theoretically systematic codes. In many practical cases, however, RLL codes and MTR codes may not be systematic codes of high encoding efficiency.

Hitherto, a trellis is constructed on the basis of the state-transition diagram of an encoder and an FBA (FBA decoder for trellis) is used, as has been explained with reference to FIG. 1. Thus, a series of codes equalized to acquire PR characteristic is detected in one process and RLL codes are decoded in another process. In this conventional method, the interference between the bits constituting the codes of the series cannot be utilized to decode the RLL codes.

Thus, it is demanded that the error rate of the data decoded be more decreased than by the conventional method in which the codes are detected in one process and the RLL codes are decoded in another process.

The present invention has been made in view of the foregoing. An object of the invention is to decrease the error rate in the process of decoding data.

### SUMMARY OF THE INVENTION

According to the present invention, there is provided a decoding apparatus which comprises decoding means for decoding encoded data in a method described by a first finite state transition diagram, by using a trellis corresponding to a second finite state transition diagram that is a combination of the first finite state transition diagram and intersymbol interference. The encoded data has been generated by encoding a series of information.

In the decoding apparatus, the first finite state transition diagram may be one that accords with (2, 7) RLL conversion rules.

In the decoding apparatus, the first finite state transition diagram may be one that accords with (1, 7) RLL conversion rules.

In the decoding apparatus, the intersymbol interference may be based on a partial-response equalization system.

In the decoding apparatus, the encoded data may further be encoded into LDPC codes or turbo codes. The decoding apparatus may further comprise second decoding means for receiving the information decoded by the first decoding means and decoding the LDPC codes or turbo codes.

The decoding apparatus may further comprise reproducing means for reproducing the encoded data generated in the method described by the first finite state transition diagram. The first decoding means may use the trellis corresponding to the second finite state transition diagram, thereby to decode the encoded data that the reproducing means has reproduced from a predetermined recording medium.

The decoding apparatus may further comprise receiving means for receiving the encoded data generated in the method described by the first finite state transition diagram and transmitted via a predetermined communication path. The first decoding means may decode the encoded data received by the receiving means, by using the trellis corresponding to the second finite state transition diagram.

According to this invention, there is provided a decoding method which comprises the steps of: acquiring encoded data generated by encoding a series of information in a method described by a first finite state transition diagram; and decoding the encoded data acquired, by using a trellis corresponding to a second finite state transition diagram that is a combination of the first finite state transition diagram and intersymbol interference.

According to the invention, there is provided a program-stored medium storing a computer-readable program that describes the steps of: acquiring encoded data generated by encoding a series of information in a method described by a first finite state transition diagram; and decoding the encoded data acquired, by using a trellis corresponding to a second finite state transition diagram that is a combination of the first finite state transition diagram and intersymbol interference.

According to this invention, there is provided a program that describes the steps of: acquiring encoded data generated by encoding a series of information in a method described by a first finite state transition diagram; and decoding the encoded data acquired, by using a trellis corresponding to a second finite state transition diagram that is a combination of the first finite state transition diagram and intersymbol interference.

According to the present invention, there is provided a recording/reproducing apparatus which comprises: encoding means for encoding a series of information in a method described by a first finite state transition diagram; recording/reproducing means for recording and reproducing data encoded by the encoding means, in and from a predetermined recording medium; and decoding means for decoding the encoded data reproduced by the recording/reproducing means, by using a trellis corresponding to a second finite state transition diagram that is a combination of the first finite state transition diagram and intersymbol interference.

According to an aspect of the present invention, it is possible to decode the data that has been encoded. Particularly, it can decode encoded data, by using a finite state transition diagram that accords with the (2, 7) RLL or (1, 7) RLL conversion rules and by utilizing a trellis that corresponds to a finite state transition diagram showing the interference between PR1-channel codes.

According to another aspect of the invention, it is possible to record and reproduce data that has been encoded in accordance with RLL conversion rules, and also to decode encoded data reproduced, by using a finite state transition diagram that accords with the RLL conversion rules and by utilizing a trellis that corresponds to a finite state transition diagram showing the interference between PR1-channel codes.

### BRIEF DESCRIPTION OF THE SEVERAL VIEWS OF THE DRAWING

FIG. 1 is a block diagram showing a conventional recording/reproducing apparatus;

FIG. 2 is a five-state transition diagram that describes how the input data is encoded into (2, 7) RLL codes;

FIG. 3 is a state-transition diagram for a PR1 channel with a precoder, which has the restriction of d=2;

FIG. 4 shows a trellis diagram that is designed for the PR channel having the precoder which has the restriction of d=2;

FIG. 5 shows a trellis diagram that is designed for RLL codes;

FIG. 6 is a block diagram showing the configuration of a recording/reproducing apparatus according to this invention;

FIG. 7 is a block diagram of a coded data transmitting system that comprises an encoding apparatus and a decoding apparatus, according to the present invention;

FIG. 8 is a diagram explaining a five-state transition table that is utilized to encode input data into (2, 7) RLL codes;

FIG. 9 is a diagram explaining a state-transition table for (2, 7) RLL codes, which is used in the PR·RLL detecting/decoding unit shown in FIGS. 6 and 7;

FIG. 10 is a trellis diagram that corresponds to the state-transition table shown in FIG. 9;

FIG. 11 is a graph representing the bit error rate observed in the conventional decoding method, in comparison the bit error rate observed in the decoding method performed on the basis of the state-transition table shown in FIG. 9;

FIG. 12 is a five-state transition diagram that is utilized to encode input data into (1, 7) RLL codes;

FIG. 13 is a diagram explaining a five-state transition table that is utilized to encode input data into (1, 7) RLL codes;

FIG. 14 is a state-transition diagram for a PR1 channel with a precoder, which has the restriction of d=1;

FIG. 15 is a diagram explaining a state-transition table for (1, 7) RLL codes, which is used in the PR·RLL detecting/decoding unit shown in FIGS. 6 and 7;

FIG. 16 is a trellis diagram that corresponds to the state-transition table shown in FIG. 15;

FIG. 17 is a graph representing the bit error rate observed in the conventional decoding method, in comparison the bit error rate observed in the decoding method performed on the basis of the state transition table shown in FIG. 15;

FIG. 18 is a flowchart explaining the process performed by the PR·RLL detecting/decoding unit shown in FIGS. 6 and 7; and

FIG. 19 is a block diagram illustrating the configuration of a personal computer.

### DETAILED DESCRIPTION OF THE INVENTION

Embodiments of the present invention will be described, with reference to the accompanying drawings.

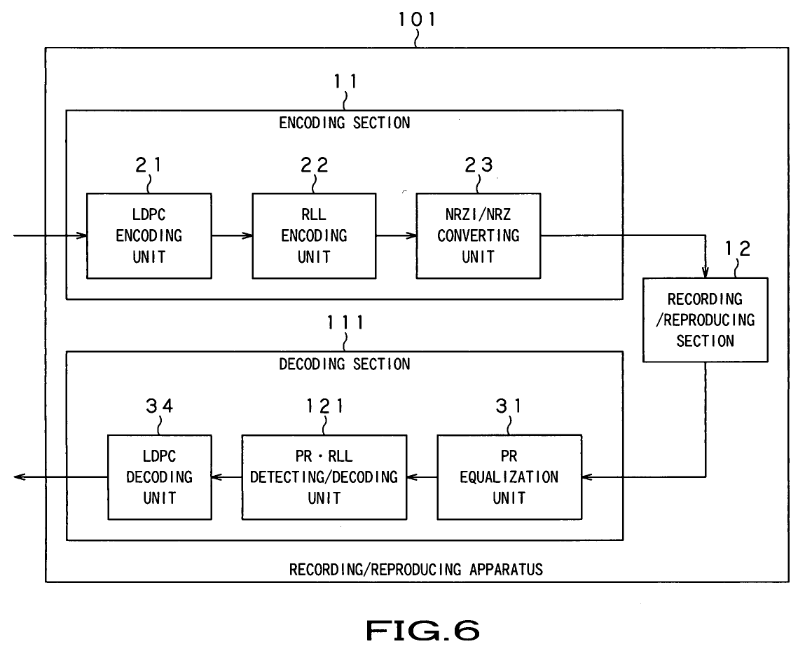

FIG. 6 is a block diagram showing the configuration of a recording/reproducing apparatus 101 according to this invention. The components identical to those of the conventional apparatus 1 are designated at the same reference numerals and will not be described unless otherwise necessary.

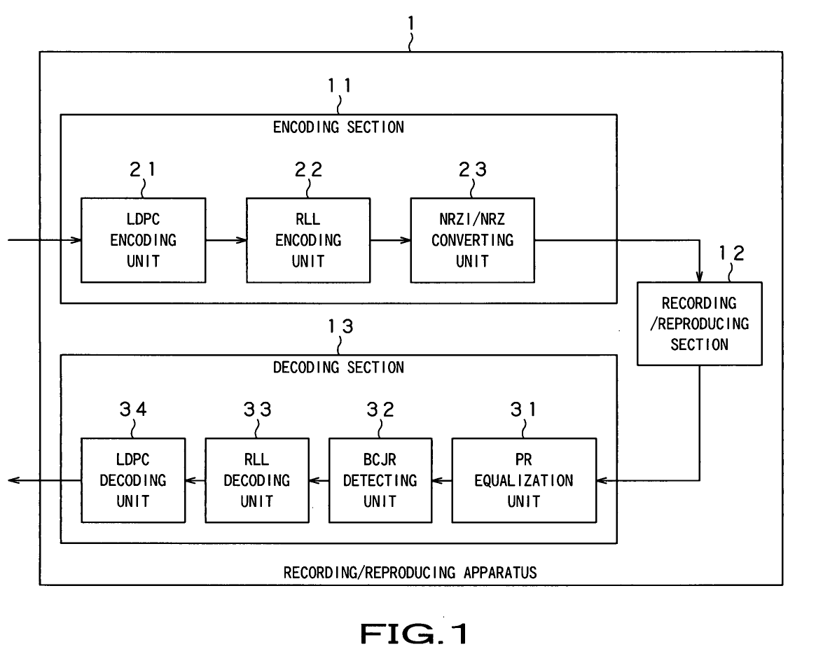

The apparatus 101 differs in configuration from the conventional apparatus 1 shown in FIG. 1, only in that a decoding section 111 is provided in place of the decoding section 13 (FIG. 1).

The encoding section 11 encodes the data input to it. The recording/reproducing section 12 incorporates a recording medium. The section 12 receives the encoded data from the encoding section 11 and records this data in the recording medium and reads the encoded data from the recording medium. The data read by the section 12 is supplied to the decoding section 111. The decoding section 111 comprises a PR equalization unit 31, an LDPC decoding unit 34, and a PR·RLL detecting/decoding unit 121. The decoding section 111 can decode the encoded data supplied to it.

Needless to say, the recording/reproducing section 12 may reproduce the encoded data recorded in the recording medium, and the decoding section 111 may decode the data supplied from the recording/reproducing section 12.

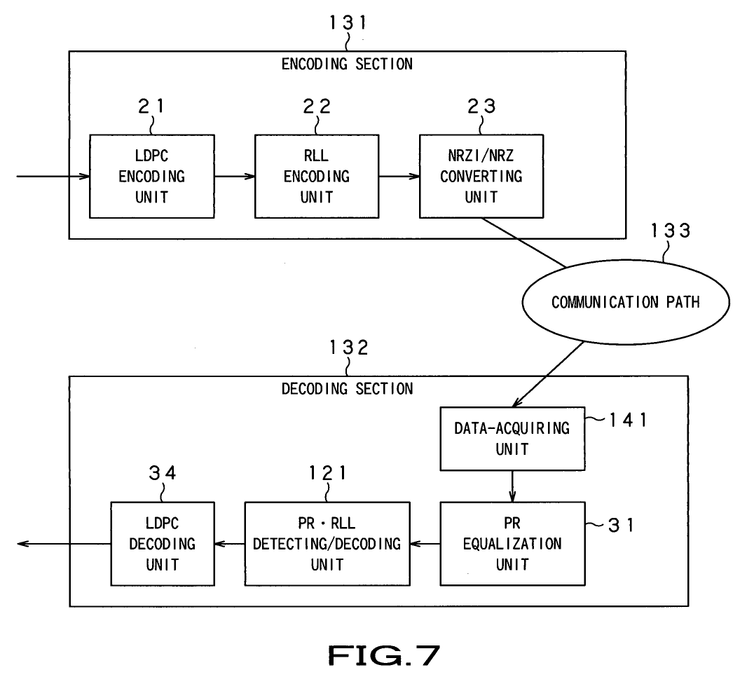

FIG. 7 is a block diagram that shows a coded data transmitting system to which the present invention is applied. As FIG. 7 depicts, the system comprises an encoding apparatus 131, a decoding apparatus 132, and a communication path 133. The encoding apparatus 131 is similar in structure to the encoding section 11 of the recording/reproducing apparatus 101 shown in FIG. 6. The apparatus 131 encodes the data input to it. The data encoded by the apparatus 131 is transmitted to the decoding apparatus 132 through the communication path 133. The communication path 133 is, for example, a radio path, a cable or an optical fiber. The decoding apparatus 132 decodes the encoded data transmitted from the encoding apparatus 131. The decoding apparatus 132 can decode the encoded data in the same way as the decoding section 111 shown in FIG. 6.

The decoding apparatus 132 shown in FIG. 7 is different in configuration from the decoding section 111 of the recording/ reproducing apparatus 101 (FIG. 6), only in that it comprises an additional component, i.e., a data-acquiring unit 141. The data-acquiring unit 141 receives the encoded data transmitted via the communication path 133 such as a radio path, a cable or an optical fiber.

The output of the PR channel can be converted to digital data. In this case, information can be transmitted from the coded-data transmitting system to any receiving station through the Internet or a LAN (Local Area Network). In the receiving station, the information may be decoded.

In the recording/reproducing apparatus 101 shown in FIG. 6, and in the encoding apparatus 131 and decoding apparatus 132, both illustrated in FIG. 7, data may be recorded and reproduced in the form of turbo codes, not LDPC codes. If this is the case, the encoding section 11 and the encoding apparatus 131 must comprise a turbo encoding unit for encoding data into turbo codes, instead of the LDPC encoding unit 21. Further, the decoding section 111 and the decoding apparatus 132 must comprise a turbo decoding unit for decoding turbo codes, instead of the LDPC decoding unit 34.

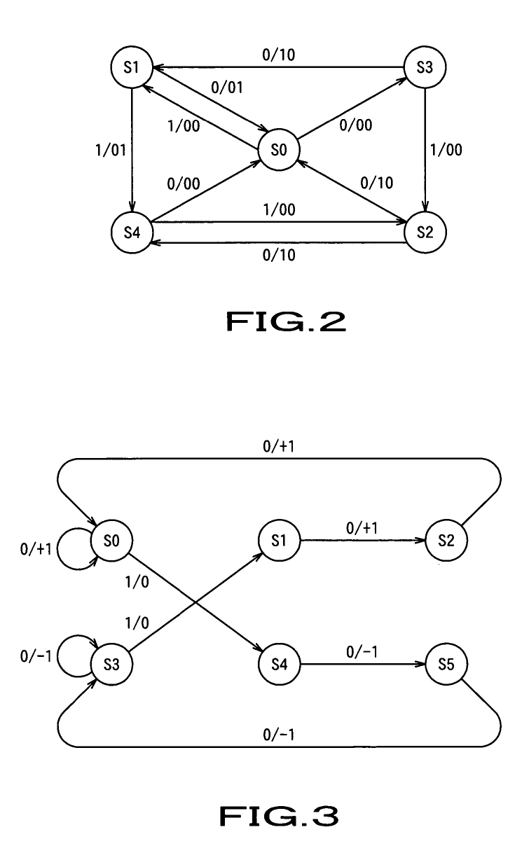

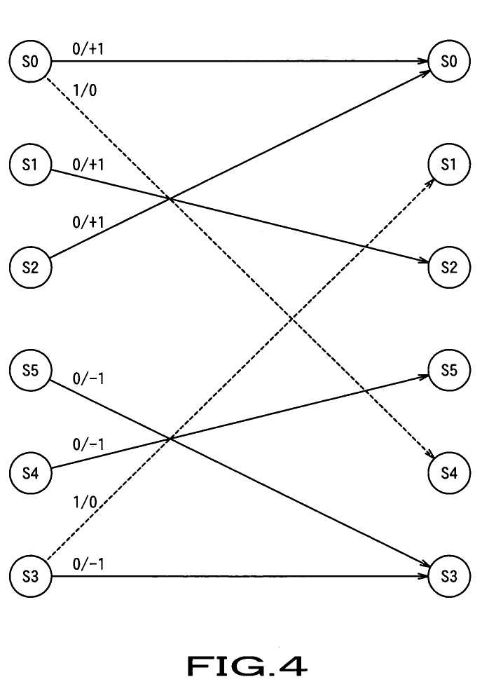

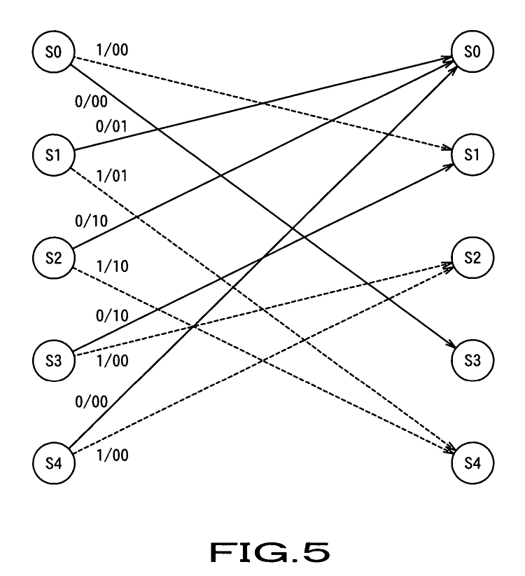

The decoding that the PR·RLL detecting/decoding unit 121 shown in FIGS. 6 and 7 perform will be described, in comparison with the decoding that the decoding section 13 performs in the conventional apparatus 1 (FIG. 1) on the basis of the transition diagram of FIG. 2 and trellis of FIG. 5.

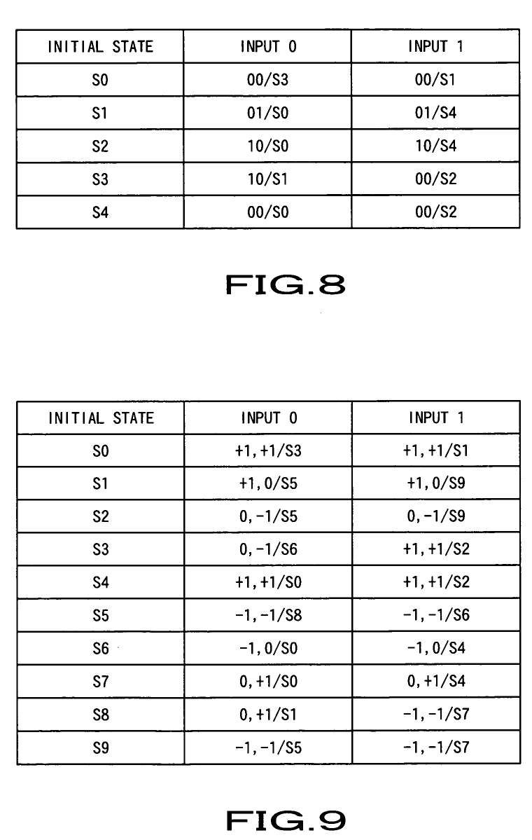

FIG. 8 is a state-transition table that is equivalent to the state-transition diagram of FIG. 2. In this table, the first column shows various initial states, the second column shows the code bits and next state for each information bit“0,” and the third column shows the code bits and next state for each information bit“1.” The RLL encoding unit 22 encodes data into (2, 7) RLL codes on the basis of the state-transition table of FIG. 8. Therefore, the decoding section 13 of the conventional recording/reproducing apparatus 1 uses the trellis of FIG. 5, which corresponds to the state-transition table of FIG. 8, in order to decode any code detected.

FIG. 9 is a state-transition table that the PR·RLL detecting/decoding unit 121 uses to decode codes. This table is applied when data is encoded into (2, 7) RLL codes for the PR1 channel that has a precoder. In the table of FIG. 9, the first column shows various initial states, the second column shows the channel output and next state for each information bit“0.” and the third column shows the channel output and next state for each information bit“1.”

The ten states S0 to S9 shown in the state-transition table of FIG. 9 correspond to those defined by dividing each of the states S0 to S4 shown in the table of FIG. 8 into two transition states. Thus, the states S0 to S4 shown in FIG. 9 correspond to the cases where the immediately preceding NRZ code is“0” in the state-transition table of FIG. 8. Similarly, the states S5 to S9 shown in FIG. 9 correspond to the cases where the immediately preceding NRZ code is“1” in the state-transition table of FIG. 8.

The next state for each input listed in the state-transition table of FIG. 9 is changed or not changed from the corresponding state shown in FIG. 8, in accordance with whether the polarity is inverted or not. This can be understood by comparing the next states listed in FIG. 9 with the next states listed in the table of FIG. 8. That is, in the states S0 to S4, the next states for two bits (i.e., code bits“00”) that do not change in polarity in FIG. 8 are those in which the NRZ code is 0 (i.e., states S0 to S4); and the next states for two bits (i.e., code bits“01” or“10”) that change in polarity only once in FIG. 8 are those in which NRZ code is 1 (i.e., states S5 to S9). In the states of S5 to S9, the next states for two bits that do not change in polarity in FIG. 8 are those in which the NRZ code is 1 (i.e., states S5 to S9), and the next states for two bits that change in polarity only once in FIG. 8 are those in which NRZ code is 0 (i.e., states S0 to S4).

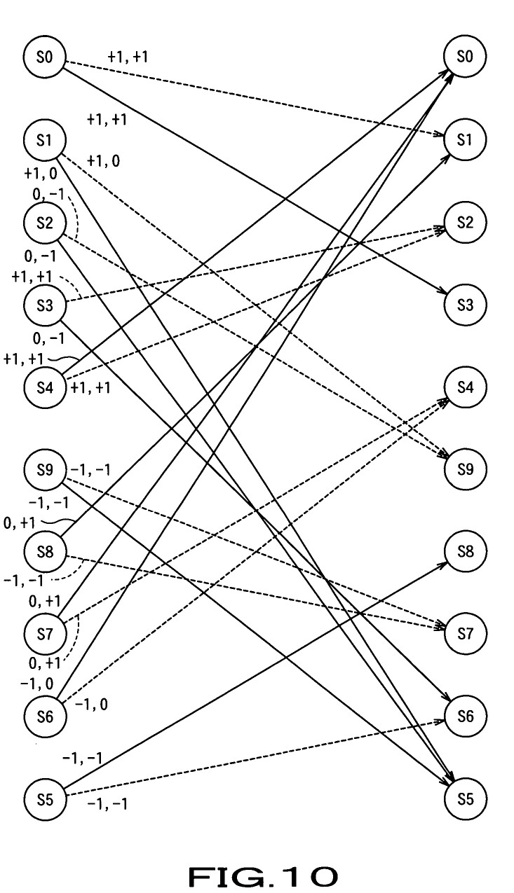

Namely, the PR·RLL detecting/decoding unit 121 shown in FIGS. 6 and 7 is either a viterbi decoder or APP detector that decodes the input codes, by using the trellis of FIG. 10. Note that this trellis corresponds to the state-transition table of FIG. 9.

In the trellis of FIG. 10, each solid-line arrow represents a state transition that takes place if the input information bit is“0,” and each broken-line arrow depicts a state transition that occurs if the input information bit is“1.” The label put to each arrow indicates the channel output.

The APP detector, which is used as PR·RLL detecting/decoding unit 121, utilizes, for example, MAP algorithm, Log-MAP algorithm, Max-Log AP algorithm, or SOVA (Soft Output Viterbi Algorithm). The APP detector can generates the a posteriori probability p (0) for each information bit“0” and the a posteriori probability p (1) for each information bit“1.”

The LDPC decoding unit 34 can repeatedly decode the input code, for example ten times at most. The unit 34 uses a message-passing algorithm.

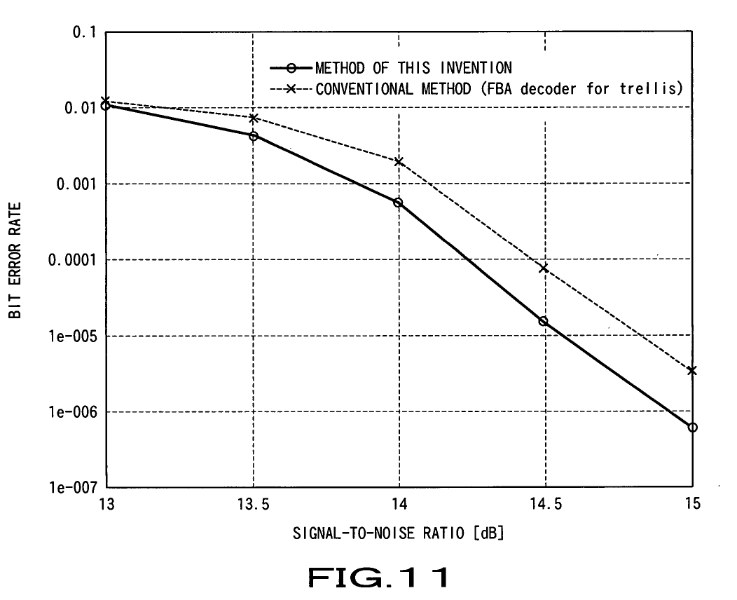

FIG. 11 shows the bit error rate observed in the conventional decoding method in which the PLL decoding unit 33 is a FBA decoder and the LDPC decoding unit 34 decodes an input code ten times using a message-passing algorithm. FIG. 11 also represents the bit error rate observed in the decoding method according to the present invention. In FIG. 11, the bit error rates are plotted on the ordinate and the signal-to-noise ratios are plotted on the abscissa. Also in FIG. 11, the solid line indicates how the bit error rate changes with the signal-to-noise ratio in the decoding method of this invention, and the broken line shows how the bit error rate changes with the signal-to-noise ratio when the RLL decoding unit 33 is a FBA decoder.

As evident from FIG. 11, the bit error rate indicated by the solid line is smaller for every signal-to-noise ratio, than the bit error rate indicated by the broken line. Thus, the present invention can achieve lower bit error rates than in the conventional data-decoding methods.

In the embodiment described with reference to FIGS. 6 to 11, a (2, 7) RLL encoder and a PR1 channel with a precoder are used in combination. Nonetheless, the present invention can be applied to any case where the minimum run length d and maximum run length k take any other values.

The PR1 channel with a precoder may be combined with an RLL code other than a (2, 7) RLL code. A case wherein the PR channel with a precoder is combined with a (1, 7) RLL code will be described below.

The RLL encoding unit 22 shown in FIGS. 6 and 7 may encode the input data in accordance with the (1, 7) RLL conversion rules. Then, the PR equalization unit 31 shown in FIGS. 6 and 7, too, carries out PR1 equalization and the PR·RLL detecting/decoding unit 121 decodes the input data code by utilizing a trellis corresponding to a state-transition table that is a combination of (1, 7) RLL codes at a encoding ratio of 2:3 and the PR1 channel with a precoder.

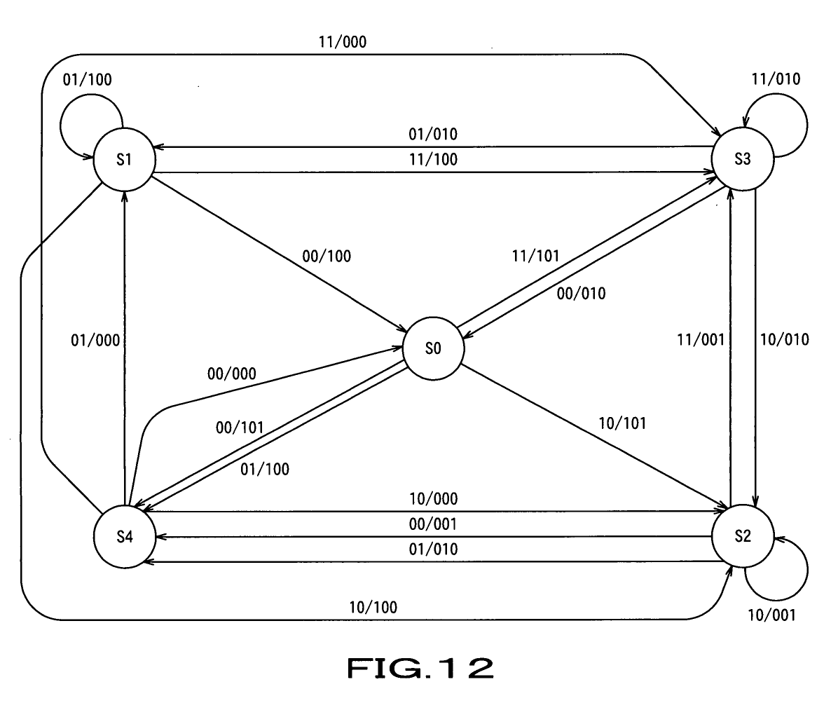

FIG. 12 is a five-state transition diagram that is utilized to encode input data into (1, 7) RLL codes. Of the label of each arrow shown in FIG. 12, the numerals at the front and back of the virgule are the input information bits and the output code bits, respectively. All of these bits pertain to encoding ratio of 2:3. Hence, the input information consists of two bits, whereas the output code consists of three bits.

The RLL encoding unit 22 shown in FIGS. 6 and 7 may encode the input data in accordance with the (1, 7) RLL conversion rules. In this case, the unit 22 outputs a code (100) when data“00” is input to it while the unit 22 remains in state S1 and the state changes to state S0, as is seen from the five-state transition diagram of FIG. 12. When data“11” is input to it while the unit 22 remains in state S1, the RLL encoding unit 22 outputs a code (100) and the state changes to state S3.

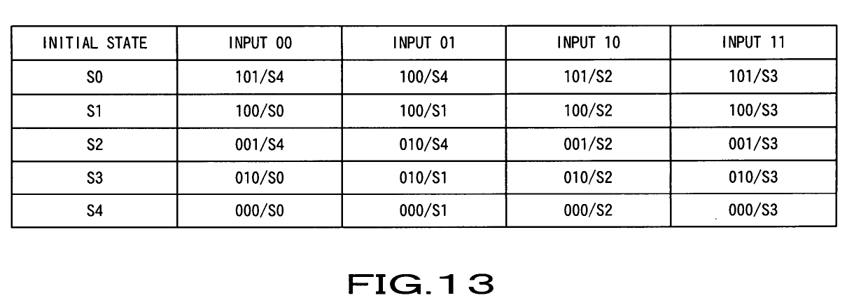

FIG. 13 is a state-transition table that is equivalent to the state-transition diagram of FIG. 12. In the table of FIG. 13, the first column shows various initial states, the second column shows the code bits and next state for information bits“00,” the third column shows the code bits and next state for information bits“01,” the fourth column shows the code bits and next state for information bits“10,” and the fifth column shows the code bits and next state for information bits“11.”

That is, the RLL encoding unit 22 described with reference to FIG. 1 encodes the input data into (1, 7) RLL codes, on the basis of the state-transition table illustrated in FIG. 13. Therefore, the decoding section 13 of the conventional recording/reproducing apparatus 1 uses the trellis that corresponds to the state-transition table of FIG. 13, in order to decode any code detected.

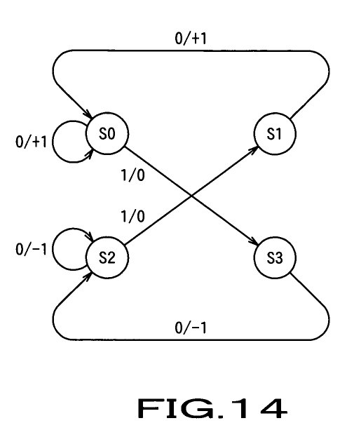

FIG. 14 is a state-transition diagram applied to the PR channel with a precoder, when there is the limitation of: d=1. In this case,“0” and“1” contained in the NRZ are mapped into“+1” and“−1,” respectively, and the transfer function of PR is: H(D)=(1+D)/2, where D is a delay operator.

Assume that the BCJR detecting unit 32 (FIG. 1) detects codes on the basis of the state-transition diagram of FIG. 14. Then,“+1” is channel-output for the code bit“0” in state S0. As a result, the state of the unit 32 remains unchanged. When the channel output“0” is generated for the code bit“1” in state S0, the state of the unit 32 is changed, from state S0 to state S3.

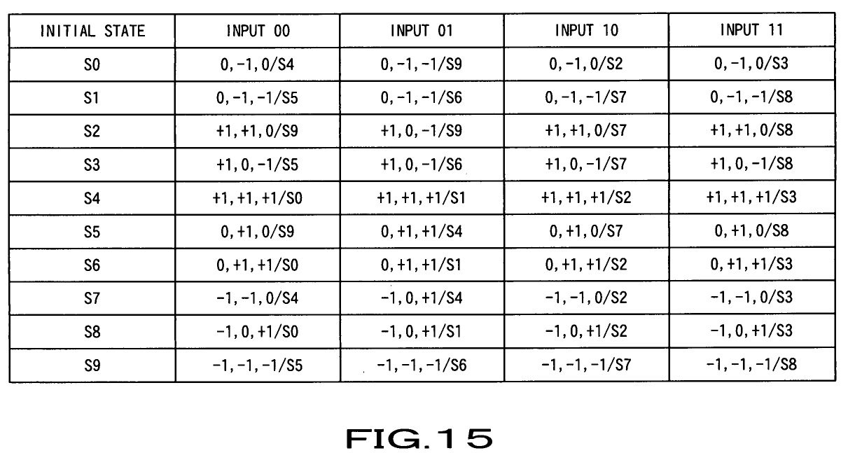

FIG. 15 is the state-transition table that the PR·RLL detecting/decoding unit 121 uses to decode any PR1-channel code generated by encoding data in accordance with the (1, 7) RLL conversion rules. This table is applied when the PR channel with a precoder is combined with a (1, 7) RLL code. In FIG. 15, the first column shows various initial states, the second column shows the channel output and next state for information bits “00,” the third column shows the channel output and next state for information bits“01,” the fourth column shows the channel output and next state for information bits “10,” and the fifth column shows the channel output and next state for information bits “11.”

The ten states S0 to S9 shown in the state-transition table of FIG. 15 correspond to those defined by dividing each of the states S0 to S4 shown in the table of FIG. 13 into two transition states. Thus, the states S0 to S4 shown in FIG. 15 correspond to the cases where the immediately preceding NRZ code is“0” in the state-transition table of FIG. 13. Similarly, the states S5 to S9 shown in FIG. 15 correspond to the cases where the immediately preceding NRZ code is“1” in the state-transition table of FIG. 13.

In the same way as explained with reference to FIG. 9, the next state for each input listed in the state-transition table of FIG. 15 is changed or not changed from the corresponding state shown in FIG. 13, in accordance with whether the polarity is inverted or not. This can be understood if the next states listed in FIG. 15 are compared with the next states listed in the table of FIG. 13. That is, in the states S0 to S4, the next states for three bits (i.e., code bits“000” or“101”) that change in polarity an even number of times in FIG. 13 are those in which the NRZ code is 0 (i.e., states S0 to S4); the next states for three bits (i.e., code bits“001”, “010” or“100”) that change in polarity an odd number of times in FIG. 13 are those in which NRZ code is 1 (i.e., states S5 to S9). In the states of S5 to S9, the next states for three bits that change in polarity an even number of times in FIG. 13 are those in which the NRZ code is 1 (i.e., states S5 to S9); and the next states for three bits that change in polarity an odd number of times in FIG. 13 are those in which NRZ code is 0 (i.e., states S0 to S4).

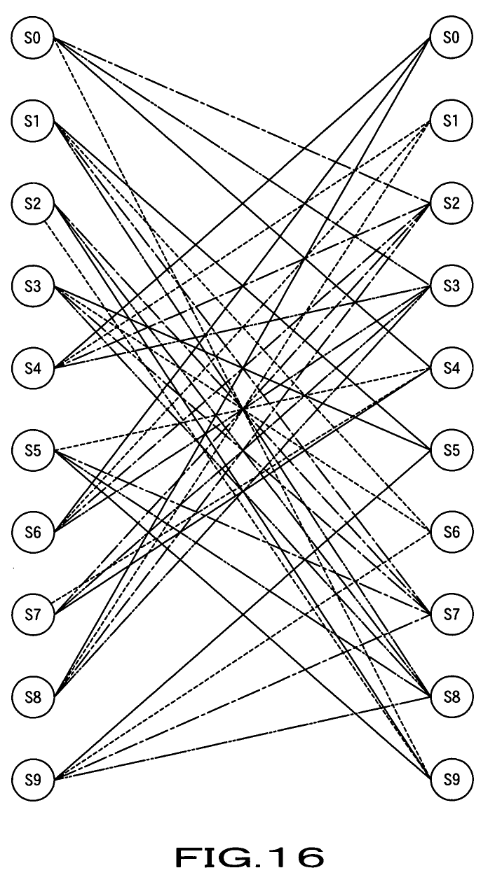

Namely, the PR·RLL detecting/decoding unit 121 shown in FIGS. 6 and 7 is either a viterbi decoder or APP detector that decodes the channel output of data encoded in accordance with the (1, 7) RLL conversion rules. It should be noted that this trellis of FIG. 16 corresponds to the state transition table of FIG. 15.

In the trellis of FIG. 16, each solid line represents a state transition that takes place if the information bits input are“00,” and each broken line depicts a state transition that occurs if the information bits input are“01.” Each one-dot dashed line displays a state transition that occurs if the information bits input are“10.” Each two-dot, dashed line indicates a state transition that takes place if the information bits input are“11.” In FIG. 16, the values of the channel outputs are not specified. In each state, any channel output has the same relation with the input information bits as is specified in the state-transition table of FIG. 15.

Thus, the PR·RLL detecting/decoding unit 121 shown in FIGS. 6 and 7 utilizes the trellis shown in FIG. 16, which corresponds to the state-transition table of FIG. 15. Using the trellis, the unit 121 finds the a posteriori probability for every two information bits. From the probability, a posteriori probabilities p(0) and p(1) for information bits“0” and“1”, respectively, are obtained.

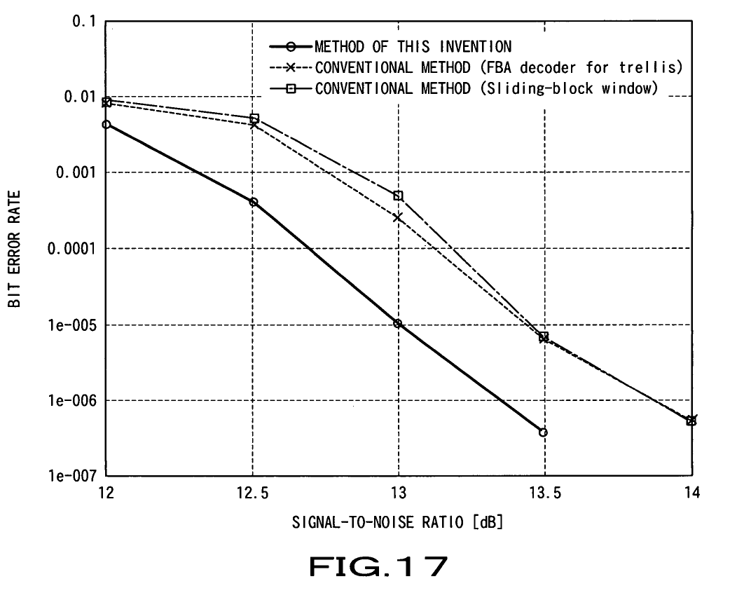

FIG. 17 shows the bit error rates observed in three methods of decoding data from the PR1 channel output in accordance with the (1, 7) RLL conversion rules. In the first method, the data is decoded by using the present invention. In the second method, the data is decoded by using a conventional FBA decoder. In the third method, the data is decoded by using a sliding-block window. All the bit error rates are measured at the end of the LDPC decoding unit 34 that uses a message-passing algorithm and decodes an input code ten times. In FIG. 17, the bit error rates are plotted on the ordinate and the signal-to-noise ratios are plotted on the abscissa.

In FIG. 17, each solid line indicates a bit error rate observed when the present invention is used, each broken line represents a bit error rate observed when the conventional FBA decoder is used, and each one-dot dashed line shows a bit error rate observed when a conventional sliding-block window is used. As evident from FIG. 17, the bit error rate indicated by any solid line is smaller for every signal-to-noise ratio, than the bit error rate indicated by any broken line or any one-dot dashed line. Thus, the present invention can achieve lower bit error rates than in the conventional data-decoding methods.

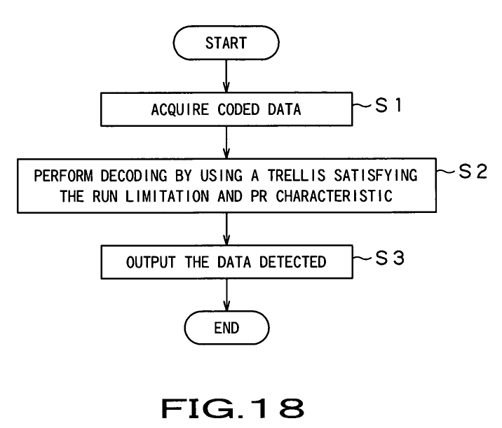

With reference to the flowchart of FIG. 18, it will be described how the PR·RLL detecting/decoding unit 121 shown in FIGS. 6 and 7 decodes the codes supplied to it.

In step S1, the PR equalization unit 31 acquires the data reproduced from the recording medium connected to or incorporated in the recording/reproducing section 12, or the data transmitted via the communication path 133 to the data-acquiring unit 141. The PR equalization unit 31 performs equalization on the data thus acquired. The data equalized is supplied to the PR·RLL detecting/decoding unit 121.

In step S2, the PR·RLL detecting/decoding unit 121 decodes the channel output supplied in step S1, by using a trellis that satisfies PR characteristic and the run length limitation of the encoding method the encoding section 11 or encoding apparatus 131 has carried out.

The trellis shown in FIG. 10 is used in step S2, if the codes to be decoded have been generated on the basis of, for example, the (2, 7) RLL conversion rules. If the codes have been generated on the basis of the (1, 7) RLL conversion rules, the trellis shown in FIG. 16 is used in step S2.

In step S3, the PR·RLL detecting/decoding unit 121 outputs the information obtained by decoding the channel output in step S2. The process is thus terminated. The PR·RLL detecting/decoding unit 121 may be an APP detector. If this is the case, the data representing posteriori probabilities p(0) and p(1) for information bits“0” and“1”, respectively, is output, and the process is completed.

The data output in step S3 is decoded by the LDPC decoder 34. If the data encoded in step S1 is, for example, a turbo code, and is not an LDPC code, however, the data output in step S3 is supplied to, and decoded by, a decoding unit that decodes turbo codes.

Thus, the data can be decoded at a lower bit error rate than in the conventional decoding methods, as has been explained with reference to FIG. 11 or 17.

The sequence of the steps described above can be carried out by using software. The software may be a program stored in a hardware unit that is incorporated in a dedicated computer. Alternatively, it may be a program installed into a general-purpose computer that can perform various functions in accordance with other programs installed.

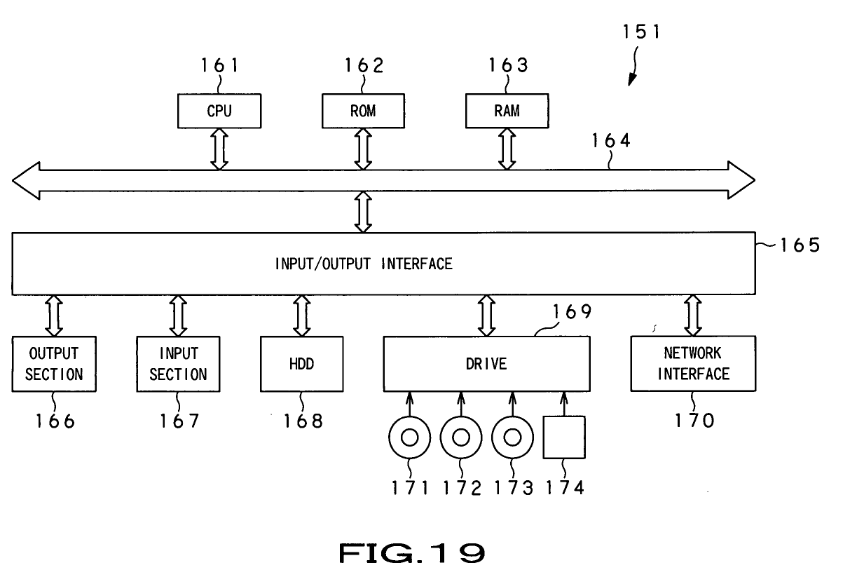

FIG. 19 shows a personal computer 151 that performs the process described above. The computer 151 comprises a CPU (Central Processing Unit) 161, a ROM (Read Only Memory) 162, a RAM (Random Access Memory) 163, and an HDD 168. The CPU 161 performs various processes in accordance with the program stored in the ROM 162 and the program stored into the RAM 163 from the HDD 168. The RAM 163 may store, if necessary, the data the CPU 161 requires in order to carry out various processes.

The CPU 161, ROM 162 and RAM 163 are connected to one another by an internal bus 164. An input/output interface 165 is connected to the internal bus 164.

To the input/output interface 165, there are connected an input section 167, an output section 166, the HDD (Hard Disc Drive) 168, a modem (not shown), and a network interface 170. The input section 167 comprises a keyboard, a mouse and the like. The output section 166 comprises a display, speakers and the like. The display that displays images and text data may be a CRT (Cathode Ray Tube), an LCD (Liquid Crystal Display) or the like. The speakers generate speech and sound. The HDD 168 records and reproduces data. The network interface 170 is a modem, a terminal adapter or the like and serves to accomplish data communication through a network such as the Internet.

A drive 169 is connected, if necessary, to the input/output interface 165. The drive 169 holds a magnetic disc 171, an optical disc 172, a magneto optical disc 173, or a semiconductor memory 174. The computer program read from the disc 171, 172 or 173 or from the semiconductor memory 174 is installed, if necessary, into the HDD 168.

The recording medium in which the program for executing the sequence of the above-described steps is recorded is distributed to the user of the computer 151, thus providing the user with the program. The medium is available in the form of a package medium, such as the magnetic disc 171 that records the program including a flexible disc, the optical disc 172 including a CD-ROM (Compact Disc-Read Only Memory) and a DVD (Digital Versatile Disc), the magneto optical disc 173 including MD (Mini-Disc, trademark), or the semiconductor memory 174.

The steps described in the program that is stored in the recording medium are performed in the sequence specified above. Nonetheless, they may be carried out in parallel or independently.

1. A decoding apparatus comprising:
acquiring means for acquiring encoded data in a method described by a first finite state transition diagram; and
means for decoding the acquired encoded data by using a trellis corresponding to a second finite state transition diagram that is a combination of the first finite state transition diagram and intersymbol interference, said encoded data having been generated by encoding an information series.

2. The decoding apparatus according to claim 1, wherein the first finite state transition diagram accords with (2, 7) run length limited code conversion rules.

3. The decoding apparatus according to claim 1, wherein the first finite state transition diagram accords with (1, 7) run length limited code conversion rules.

4. The decoding apparatus according to claim 1, wherein the intersymbol interference is based on a partial-response equalization system.

5. The decoding apparatus according to claim 1, in which the encoded data is further encoded into one of low density parity check (LDPC) codes and turbo codes and said decoding means comprises first decoding means, and which further comprises second decoding means for receiving the information decoded by the first decoding means and decoding one of the LDPC codes and turbo codes.

6. The decoding apparatus according to claim 1, which further comprises reproducing means for reproducing the encoded data generated in the method described by the first finite state transition diagram, and in which the decoding means uses the trellis corresponding to the second finite state transition diagram, thereby to decode the encoded data that the reproducing means has reproduced from a recording medium.

7. The decoding apparatus according to claim 1, which further comprises receiving means for receiving the encoded data generated in the method described by the first finite state transition diagram and transmitted via a predetermined communication path, and in which the decoding means decodes the encoded data received by the receiving means by using the trellis corresponding to the second finite state transition diagram.

8. A decoding method comprising the steps of:
acquiring encoded data generated by encoding an information series in a method described by a first finite state transition diagram; and
decoding the encoded data acquired in the step of acquiring by using a trellis corresponding to a second finite state transition diagram that is a combination of the first finite state transition diagram and intersymbol interference.

9. A program storage medium storing a computer-readable program that describes the steps of:
acquiring encoded data generated by encoding an information series in a method described by a first finite state transition diagram; and
decoding the encoded data acquired in said step of acquiring by using a trellis corresponding to a second finite state transition diagram that is a combination of the first finite state transition diagram and intersymbol interference.

10. A program describing the steps of:
acquiring encoded data generated by encoding an information series in a method described by a first finite state transition diagram; and
decoding the encoded data acquired in said step of acquiring by using a trellis corresponding to a second finite state transition diagram that is a combination of the first finite state transition diagram and intersymbol interference.

11. A recording/reproducing apparatus comprising:
encoding means for encoding an information series in a method described by a first finite state transition diagram;
recording/reproducing means for recording and reproducing data encoded by the encoding means, in and from a recording medium; and
decoding means for decoding the encoded data reproduced by the recording/reproducing means by using a trellis corresponding to a second finite state transition diagram that is a combination of the first finite state transition diagram and intersymbol interference.
